(19) United States
(12) Patent Application Publication
(10) Pub. No.: US 2011/0110067 A1
(43) Pub. Date: May 12, 2011

(54) ELECTRONIC DEVICE

(75) Inventors: PING-CHOU CHEN, Tu-Cheng (TW); HUA-FENG WU, Shenzhen City (CN)

(73) Assignees: HONG FU JIN PRECISION INDUSTRY (ShenZhen)CO.,LTD., Shenzhen City (TW); HON HAI PRECISION INDUSTRY CO., LTD., Tu-Cheng (TW)

(21) Appl. No.: 12/756,973

(22) Filed: Apr. 8, 2010

(30) Foreign Application Priority Data
Nov. 6, 2009 (CN) 200910309396.7

(51) Int. Cl. H05K 7/14

(52) U.S. Cl. 361/807

(57) ABSTRACT

An electronic device includes a shell, a circuit board, a triggering element, a light-transmissive button and an optical sensor. The shell defines a button hole in an edge thereof and forms a receiving space therein. The circuit board module is installed in the receiving space. The triggering element is fixed on and electronically connected with the circuit board module. The light-transmissive button is received in the button hole, and is depressible for turning on and off the triggering element. The optical sensor is positioned beneath the light-transmissive button for detecting intensity of the ambient light passing through the light-transmissive button. The appearance of the electronic device is not affected by the optical sensor.

### BACKGROUND

1. Technical Field

The present disclosure relates to an electronic device.

2. Description of Related Art

People often hope that they can use digital photo frames, e-books and other electronic devices, in any lighting conditions, whether they are in the dark or the bright sunlight. Existing electronic devices use an optical sensor to detect the surrounding light intensity and adjust the light intensity of the display accordingly, so that people can view information shown on the display in any light conditions. The optical sensor is positioned in a hole defined in the electronic device. Light can transmit into the hole and be detected by the optical sensor. Yet, the hole may affect the appearance of the electronic device.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded view of an electronic device according to an exemplary embodiment.

FIG. 2 is an enlarged view of the encircled portion II of FIG. 1.

FIG. 3 is an exploded view of FIG. 2.

### DETAILED DESCRIPTION

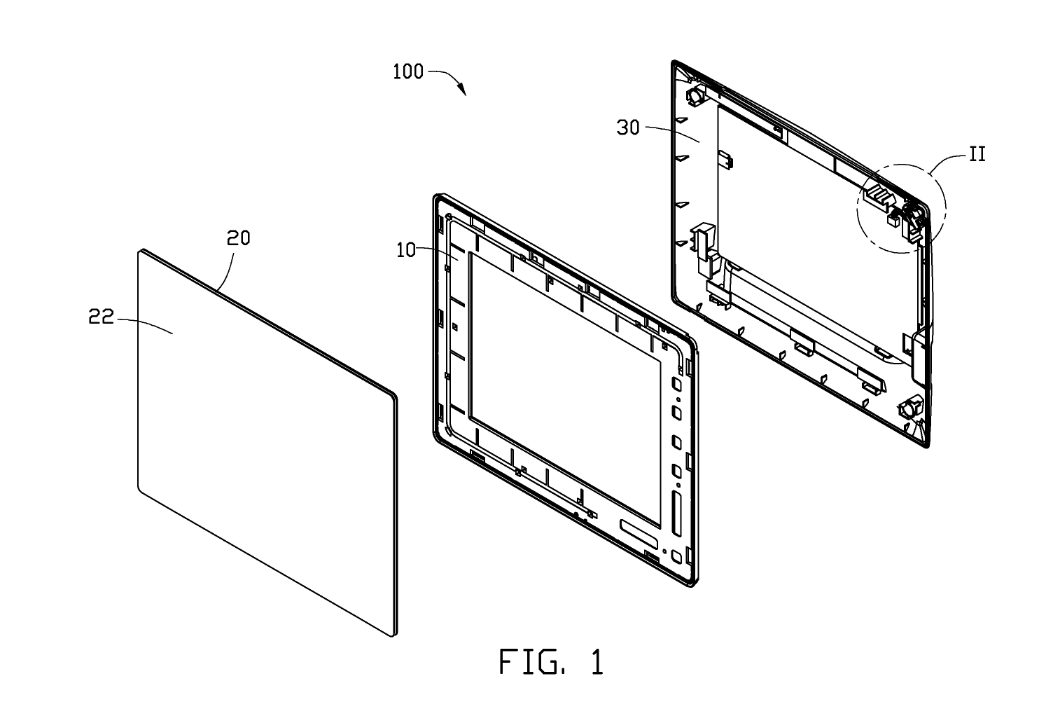

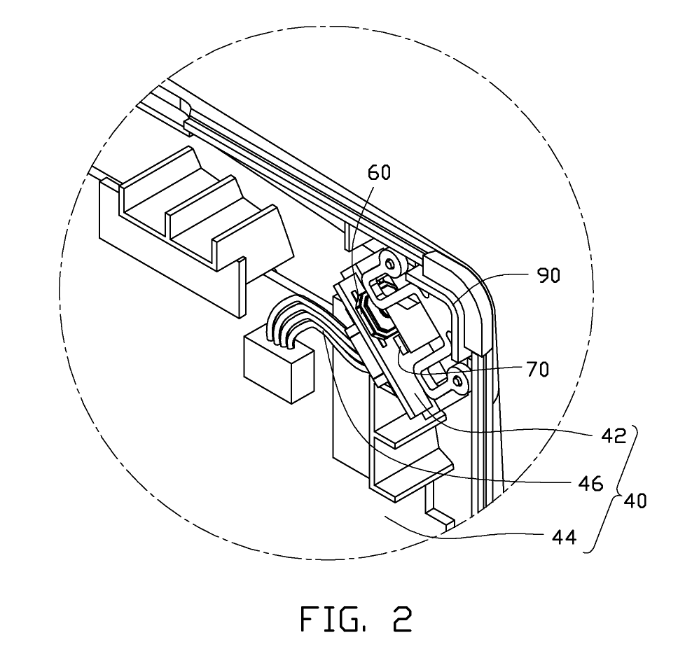

Referring to FIG. 1, an electronic device 100 according to an exemplary embodiment includes a frame 10, a panel 20, and a shell 30. The panel 20 is fixed to one side of the frame 10. The shell 30 is fixed to the other side of the frame 10, opposite to the panel 20. A display 22 is mounted on the panel 20 for displaying information. Referring to FIG. 2, the electronic device 100 further includes a circuit board module 40 installed in the shell 30, a triggering element 60, an optical sensor 70, and a light-transmissive button 90. The triggering element 60 and the optical sensor 70 are fixed on the circuit board module 40 and are electronically connected to the circuit board module 40. The light-transmissive button 90 is mounted on the shell 30 and movably contacts the triggering element 60 for turning on and off the triggering element 60.

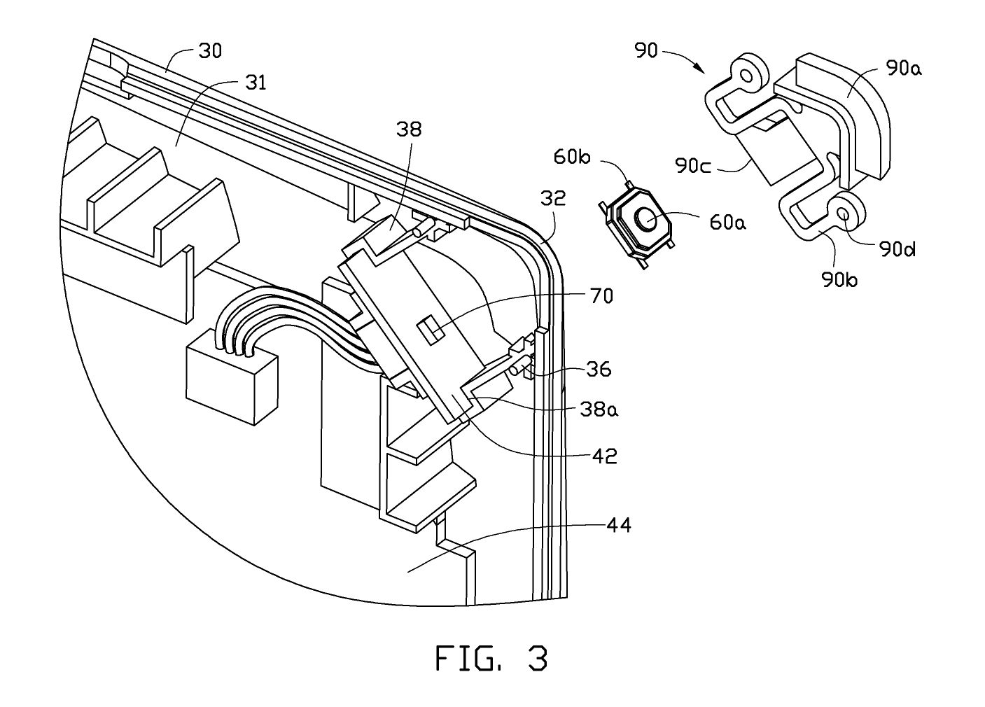

Referring to FIG. 3, the shell 30 forms a receiving space 31 configured for receiving the circuit board module 40. The circuit board module 40 includes a first circuit board 42, a second circuit board 44, and a connector 46 electronically connecting the first circuit board 42 to the second circuit board 44. The triggering element 60 and the optical sensor 70 are fixed on the first circuit board 42, and communicate with the second circuit board 44 via the connector 46. In other embodiments, the circuit board module 40 may include only one circuit board.

The shell 30 defines a button hole 32 on the shell 30. In this embodiment, the button hole 32 is defined at a corner of the shell 30. In the receiving space 31, two fixed shafts 36 configured for fixing the light-transmissive button 90 and two fixing blocks 38 configured for fixing the first circuit board 42 protrude from the shell 30. The two fixed shafts 36 are respectively located adjacent to two sides of the button hole 32. The two fixing blocks 38 are spaced from each other. Each fixing block 38 defines an opening 38a. The two openings 38a faced each other. The width of the openings 38a is consistent with the thickness of the first circuit board 42. Two ends of the first circuit board 42 are inserted into and held in the openings 38a.

The light-transmissive button 90 is movably installed in the button hole 32. Ambient light passes through the light-transmissive button 90 and reaches the optical sensor 70. The light-transmissive button 90 is flexible, so it can rebound upon release after being pressed down. In this embodiment, the light-transmissive button 90 is made of polycarbonate.

The light-transmissive button 90 includes a pressing portion 90a, two fixed portions 90b and a touching portion 90c. The shape of the pressing portion 90a is consistent with the button hole 32, thus the pressing portion 90a can be received in the button hole 32. The fixed portions 90b are substantially U-shaped and extend from two opposite sides of the touching portion 90c. The fixed portions 90b define fixing holes 90d at the free ends of the fixed portions. The fixed shafts 36 are fixed in the fixing holes 90d, thus to fix the light-transmissive button 90 on the shell 30.

The triggering element 60 includes a flexible conducting part 60a and an electric connecting part 60b. The electric connecting part 60b is electronically connected with the first circuit board 42. When the pressing portion 90a button 90 is pressed down, the touching portion 90c press the flexible conducting part 60a, the flexible conducting part 60a deforms and turns on the electric connecting part 60b, then the electric connecting part 60b transmits a triggering signal to the circuit board module 40. When the flexible conducting part 60a rebounds, the electric connecting part 60b turns off. In this embodiment, the flexible conducting part 60a is made of metal.

The optical sensor 70 facing the button hole 32 detects the intensity of the surrounding light passing through the light-transmissive button 90. The circuit board module 40 automatically adjusts parameters of the display 22 based on the detected intensity. The parameters may include brightness, contrast and so on.

The optical sensor 70 is positioned below the transmissive button 90, thus to avoid affecting the appearance of the shell 32.

It is to be understood, however, that even though numerous characteristics and advantages of the present disclosure have been set forth in the foregoing description, together with details of the structure and function of the present disclosure, the present disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. An electronic device comprising:
a shell defining a button hole and forming a receiving space therein;
a circuit board module installed in the receiving space;
a triggering element fixed on and electronically connected with the circuit board module;
a light-transmissive button received in the button hole, wherein the light-transmissive button is depressible for turning on and off the triggering element; and
an optical sensor positioned beneath the light-transmissive button for detecting intensity of ambient light passing through the light-transmissive button.

2. The electronic device of claim 1, wherein two fixed shafts are protruded from the shell, the two fixed shafts are respectively located adjacent to two sides of the button hole, the light-transmissive button includes a pressing portion, two fixed portions and a touching portion, the pressing portion is received in the button hole, each of the fixed portions defines a fixing hole, the fixed shaft is fixed in the fixing hole.

3. The electronic device of claim 2, wherein each fixed portion is substantially U shaped, the fixing hole is defined at a free end of the fixed portion.

4. The electronic device of claim 1, wherein the button hole is defined at a corner of the shell.

5. The electronic device of claim 1, wherein the circuit board module includes a first circuit board, a second circuit board, and a connector, the connector electronically connects the first circuit board to the second circuit board, the optical sensor is fixed on the first circuit board, wherein a fixing block is protruded from the shell, and is configured for holding the first circuit board.
